(19) United States
(12) Patent Application Publication
(10) Pub. No.: US 2025/0252231 A1
(43) Pub. Date: Aug. 7, 2025

(54) MACHINE LEARNING FOR CIRCUIT PREDICTION FOR SEMICONDUCTOR MIGRATION

(71) Applicant: INTERNATIONAL BUSINESS MACHINES CORPORATION, ARMONK, NY (US)

(72) Inventors: Xin Zhang, Chappaqua, NY (US); Shun Zhang, San Mateo, CA (US); Shaoze Fan, East Newark, NJ (US); Yilan Gu, Pittsburgh, PA (US); John Maxwell Cohn, Richmond, VT (US); Chuang Gan, Cambridge, MA (US)

(21) Appl. No.: 18/429,514

(22) Filed: Feb. 1, 2024

(51) Int. Cl. G06F 30/27

(52) U.S. Cl. CPC G06F 30/27

(57) ABSTRACT

A method, computer system, and a computer program product are provided. A trained machine learning model is used to predict performance of a semiconductor circuit. The using includes inputting, to the trained machine learning model, semiconductor physical characteristics of the semiconductor circuit and in response receiving, as output from the trained machine learning model, predicted performance characteristics for the semiconductor circuit. The trained machine learning model was trained on training data obtained from a prior known semiconductor circuit.

### BACKGROUND

The present invention relates generally to the fields of machine learning, machine learning training, semiconductor circuits, and using machine learning for designing and building semiconductor circuits.

### SUMMARY

According to one exemplary embodiment, a computer-implemented method is provided. A trained machine learning model is used to predict performance of a semiconductor circuit. The using includes inputting, to the trained machine learning model, semiconductor physical characteristics of the semiconductor circuit and in response receiving, as output from the trained machine learning model, predicted performance characteristics for the semiconductor circuit. The trained machine learning model was trained on training data obtained from a prior known semiconductor circuit. A computer system and computer program product corresponding to the above method are also disclosed herein.

According to another exemplary embodiment, a computer-implemented method is provided. A machine learning model is trained with training data obtained from a known semiconductor circuit. The training data includes inputs to the machine learning model that are semiconductor physical characteristics and outputs from the machine learning model that are semiconductor performance characteristics. The outputs constitute labels so that the training is supervised training. The training includes optimizing weights of the machine learning model so that the machine learning model predicts the outputs based on the inputs. A computer system and computer program product corresponding to the above method are also disclosed herein.

### BRIEF DESCRIPTION OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description.

FIG. 1 illustrates a process for semiconductor circuit migration prediction using machine learning according to at least one embodiment.

FIG. 2 illustrates a neural network used in the process of FIG. 1 according to at least one embodiment.

FIG. 3 illustrates output produced by a machine learning model that is trained and used in the process of FIG. 1 according to at least one embodiment. This output is generated in response to a machine learning model trained exclusively on data from known semiconductor circuits.

FIG. 4 illustrates output produced by a machine learning model that is trained and used in the process of FIG. 1 according to at least one embodiment. This output is generated in response to a machine learning model trained on data from known semiconductor circuits and on a small amount of data obtained for the new semiconductor circuit that is in design.

FIG. 5 illustrates sets of output produced by a machine learning model that is trained and used in the process of FIG. 1 according embodiments. These sets of output are varied based on different sets of semiconductor physical characteristics that are input regarding the new semiconductor circuit that is in design.

FIG. 6 illustrates a design for a multi-stage semiconductor circuit for which the process of FIG. 1 is implemented according to at least one embodiment.

FIG. 7 illustrates details of one of the stages of the multi-stage semiconductor circuit shown in FIG. 6 according to at least one embodiment.

FIG. 8 illustrates voltage parameter details used for simulating parameters for the multi-stage semiconductor circuit according to at least one embodiment and whose design is shown in FIGS. 6 and 7.

FIG. 9 illustrates a circuit design for determining capacitance information for use in pre-training the machine learning model in the process of FIG. 1 according to at least one embodiment.

FIG. 10 illustrates data display for the capacitance determination of FIG. 9 according to at least one embodiment.

FIG. 11 illustrates a circuit device design for obtaining drain-to-source current data for use in the process of FIG. 1 for pre-training the machine learning model according to at least one embodiment.

FIG. 12 illustrates a data display for displaying data obtained using the design of FIG. 11 for collecting drain-to-source current data for obtaining pre-training data according to at least one embodiment.

FIG. 13 illustrates a networked computer environment in which machine learning training and machine learning predictions for semiconductor circuit feature migration are utilized according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

The following described exemplary embodiments provide a computer system, a method, and a computer program product for facilitating semiconductor technology migration. Data from known semiconductor circuits for a first type of technology node are used to train a machine learning model which is then used to predict performance characteristics of another new semiconductor circuit that has a different technology node than the known semiconductor circuit has. The present embodiments encompass training a machine learning model using known semiconductor physical characteristics as input data for the machine learning model and using known semiconductor performance characteristics as output data (labels for supervised training) for the machine learning model. The actual performance characteristics of the known semiconductor circuit that are observed and recorded are used as ground truth output values for training the machine learning model. The trained machine learning model is then usable to help predict performance characteristics for new semiconductor circuits with different inputs but by using those new different inputs as the input to the trained machine learning model. In response to receiving those inputs, the trained machine learning model produces and provides output of prediction of performance characteristics for the new semiconductor circuit. This information is then usable in designing and constructing the new semiconductor circuits. Thus, the present embodiments help provide a machine learning framework for circuit performance prediction in semiconductor technology migration. By training, e.g., teaching, a machine learning model to predict performance characteristics based on some physical characteristics, design of new semiconductors can occur with more digital work and with needing fewer test runs on built physical samples.

Circuit design automation can benefit from machine learning, e.g., to help predict characteristics of a circuit and to evaluate a circuit without running time-consuming simulations. New semiconductor chip technology can improve the speed and efficiency of computers and computing in general, but migrating designs to new technology is challenging. The present embodiments help designers evaluate circuits efficiently and at an early design stage without having to complete manufacturing of new designs to learn about results. The machine learning framework presented herein utilizes data obtained in old semiconductor technologies and uses transfer learning and deep learning to train a machine learning model so that the trained machine learning model can predict circuit performance in the new technology. For example, the present embodiments facilitate creating designs for new 2 nm chip technology by predicting performance characteristics of these advanced chips based on data obtained from prior generation semiconductor chips.

The present embodiments provide a machine learning framework that can predict circuit performance in new technology nodes based on only old technology data or based on old technology data plus a small amount of new technology data. The present embodiments implement a transfer learning algorithm that uses device-level properties and data to train a neural network and further provide using that trained network to predict circuit-level properties. Transfer learning can transfer knowledge from a known semiconductor circuit to another semiconductor circuit from a different technology node so that the machine learning ability to predict performance for the semiconductor circuit in the new technology node helps with migration to the new technology node.

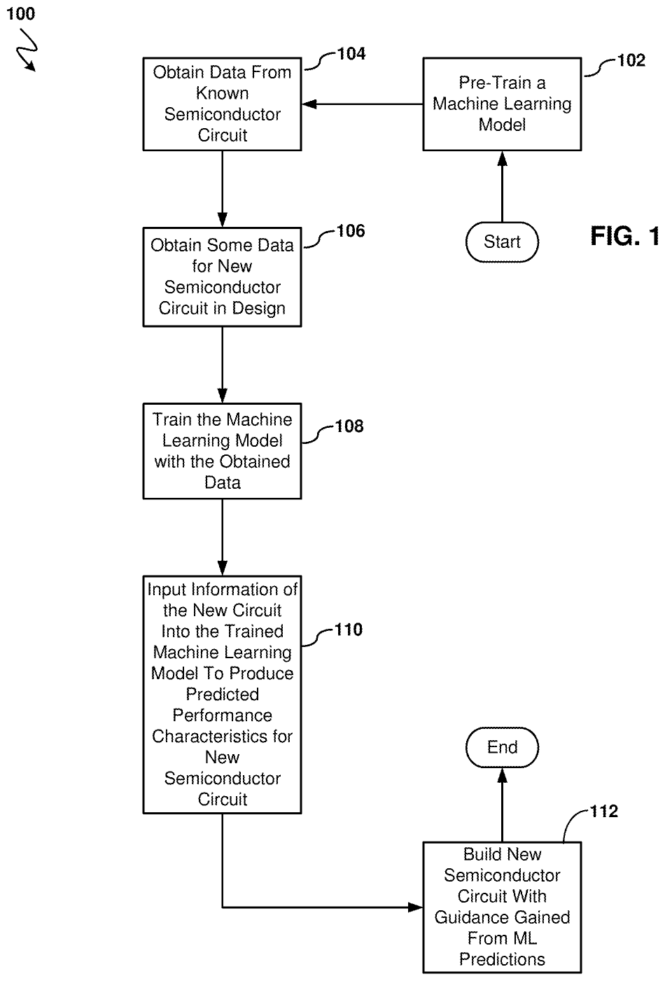

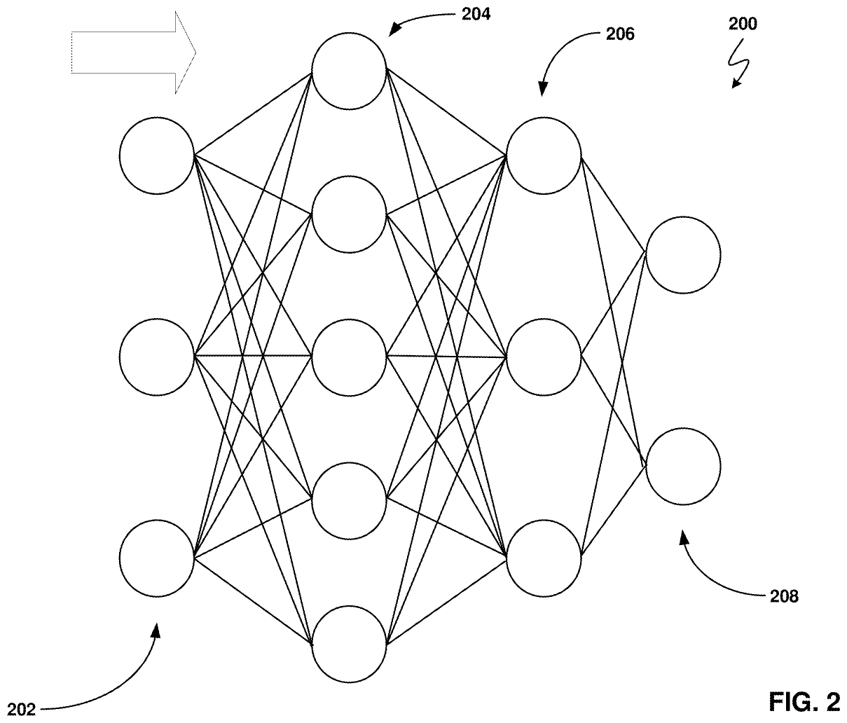

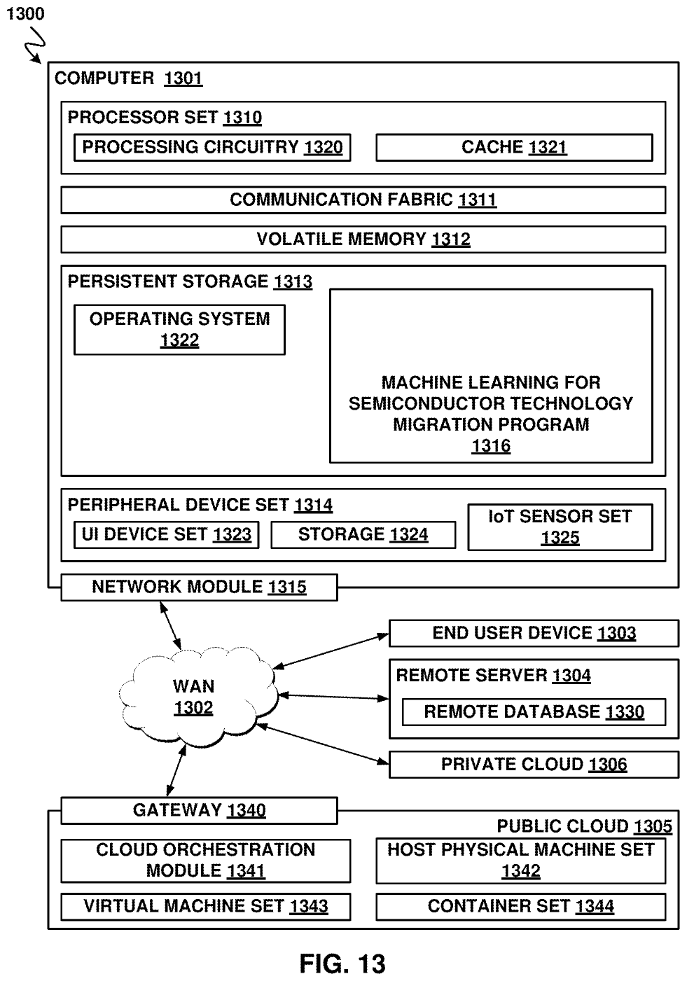

FIG. 1 illustrates a semiconductor migration machine learning process 100 according to at least one embodiment. This semiconductor migration machine learning process 100 is in at least some embodiments carried out via the semiconductor feature machine learning migration program 1316 described below and shown in the computing environment 1300 of FIG. 13. In at least some embodiments, the machine learning model trained and used in the semiconductor migration machine learning process 100 includes a neural network 200 as is shown in FIG. 2.

In step 102 of the semiconductor migration machine learning process 100, a machine learning model is pre-trained. In some instances, the machine learning model is a neural network 200 as is shown in FIG. 2. In some instances, the machine learning model includes a multi-layer perceptron network. In some instances, the machine learning model is a transformer based large language model (LLM). In some instances, the machine learning model implements classical machine learning structures and/or principles such as linear regression, Gaussian process regression, and/or decision trees. The pre-training includes inputting a set of pre-training data to the machine learning model.

The set of pre-training data includes some physical characteristics of some semiconductor circuits, e.g., of known semiconductor circuits and optionally of an in-design semiconductor circuit of a new technology. The physical characteristics in some embodiments include one or more of channel width, channel length, temperature, supply voltage, technology node, and device level information regarding the device to which the semiconductor circuit belongs. A technology node refers to a specific semiconductor manufacturing process and its design rules. The technology node designation indicates the features that a production line can create on an integrated circuit, such as interconnect pitch, transistor density, and transistor type. The machine learning model is designed to receive these values as input and predict, as output, some other values of the semiconductor circuit.

The output of the machine learning model for this pre-training exercise is one or more physical characteristics and/or one or more performance characteristics of the semiconductor circuit. In some embodiments, the output is a current, e.g., a drain-to-source current, and/or a gate capacitance of the semiconductor circuit. For example, the drain-to-source current is the output when the gate-source voltage is a certain percentage of the drain voltage of the circuit, e.g., is 30%, 50%, 60%, 70%, and/or 90% of the drain voltage or is a certain percentage of other specific voltages. In some embodiments, these values are recorded from the known semiconductor circuit in operation. The output values are considered labels as a part of supervised training for the pre-training dataset. The machine learning model, e.g., the neural network 200, is programmed to predict these output values based on the input values received. The actual recorded values are used as ground-truth values for optimizing weights of the neural network 200. For example, first predicted values of the machine learning model are compared to the ground-truth values. The weights and/or biases of the machine learning model are adjusted, e.g., via backpropagation, to adjust the machine learning model so that the predictions of the machine learning model more closely approximate the ground-truth values. The back-propagation and model adjustment occur multiple times until a difference between the predicted values and the ground-truth values is minimized, e.g., is zero over multiple epochs.

In some instances of the semiconductor migration machine learning process 100, the step 102 is skipped and the subsequent machine learning model-related steps are performed on a machine learning model which has no pre-training.

The pre-training, however, helps the machine learning model to adjust weights and/or parameters in order to predict more accurately the desired circuit characteristics for the subsequent steps of the process 100. This pre-training implements aspects of transfer learning in which training a machine learning model to predict some features helps the ability of that machine learning model to, with additional training, more accurately be able to predict other features.

In step 104 of the semiconductor migration machine learning process 100, data from known semiconductor circuits is obtained. The data in some embodiments is received via a data transmission from an external computer to the computer 1301 that hosts the program 1316. In some embodiments, the data sample is captured via an input device that is directly connected to the computer 1301. For example, a camera, a microphone, and/or a keyboard that is part of the UI device set 1323 that is part of and/or connected to the computer 901 in a wired manner captures data and transmits that data to the program 1316 within the persistent storage 1313 of the computer 1301. The data sample in some embodiments includes a text file and/or a table file with circuit characteristic titles that are disposed adjacent to respective values for the various characteristics.

The known semiconductor circuits refer to semiconductor circuits that are already manufactured and upon which actual physical and performance characteristics are measurable without needing any simulation. The semiconductor physical characteristics for the known semiconductor circuits in various embodiments include one or more of channel width, channel length, temperature, supply voltage, technology node, and device information for the device to which the circuit belongs. The semiconductor performance characteristics obtained here in step 104 refer in various embodiments to one or more of frequency, gain, bandwidth, and power.

In step 106 of the semiconductor migration machine learning process 100, some data for a new semiconductor circuit in design is obtained. The new semiconductor circuit in design refers to a semiconductor circuit that is of a different design, e.g., of a different technology node, than the known semiconductor circuit from which data was obtained in step 104. In some embodiments, the new semiconductor circuit is an analog circuit such as a ring oscillator, a bandgap reference, an amplifier, or an op-amplifier. In some embodiments, the new semiconductor circuit is a digital circuit that is synthesized by digital design tools.

The data obtained in step 106 in some embodiments is received via a data transmission from an external computer to the computer 1301 that hosts the program 1316. In some embodiments, the data sample is captured via an input device that is directly connected to the computer 1301. For example, a camera, a microphone, and/or a keyboard that is part of the UI device set 1323 that is part of and/or connected to the computer 1301 in a wired manner captures data and transmits that data to the program 1316 within the persistent storage 1313 of the computer 1301. The data sample in some embodiments includes a text file and/or a table file with circuit characteristic titles that are disposed adjacent to respective values for the various characteristics.

In step 108 of the semiconductor migration machine learning process 100, the machine learning model is trained with the obtained data. For iterations of the process 100 in which the pre-training of step 102 occurred, step 108 occurs to the pre-trained machine learning model that was a result of the pre-training of step 102. In some instances, the machine learning model is a neural network 200 as is shown in FIG. 2. In some instances, the machine learning model includes a multi-layer perceptron network. In some instances, the machine learning model is a transformer based large language model (LLM). In some instances, the machine learning model implements classical machine learning structures and/or principles such as linear regression, Gaussian process regression, and/or decision trees.

In some embodiments, step 108 is performed using only the data obtained from step 104 as the training data in step 108. In some embodiments, step 108 is performed using a combination of data obtained from step 104 and other data obtained from step 106 as the training data in step 108. Thus, either data from a known semiconductor circuit or a combination of data from a known semiconductor circuit and from a new semiconductor circuit, e.g., a semiconductor circuit in design, are used for the training data in step 108. The training includes inputting a set of training data to the machine learning model.

For the training of step 108, the machine learning model receives certain circuit physical characteristics as input and predicts, as output, some other values of the semiconductor circuit. Because the output values are known in the training data, the output values are considered labels as a part of supervised training for training the machine learning model with a training dataset. The machine learning model, e.g., the neural network 200, is programmed to predict these output values based on the other input values that it received. The actual recorded values are used as ground-truth values for optimizing weights of the neural network 200. For example, predicted values of the machine learning model are compared to the ground-truth values. The weights and/or biases of the machine learning model are adjusted, e.g., via backpropagation, to adjust the machine learning model so that the predictions of the machine learning model more closely approximate the ground-truth values. The back-propagation and model adjustment occur multiple times until a difference between the predicted and ground-truth values is minimized, e.g., is zero over multiple epochs.

In step 110 of the semiconductor migration machine learning process 100, information of the new circuit is input into the trained machine learning model to produce predicted performance characteristics for the new semiconductor circuit. The new circuit refers to a semiconductor circuit in design and/or a circuit that is of a different design and/or type, e.g., a different technology node, than the known circuit from which data was obtained in step 104. The information that is input includes physical characteristics such as one or more of channel width, channel length, temperature, drain voltage, technology node, etc. The output information includes one or more performance characteristics, such as frequency, gain, bandwidth, and power, of the new circuit.

The information that is input in step 110 in some embodiments is received via a data transmission from an external computer to the computer 1301 that hosts the program 1316. In some embodiments, the data sample is captured via an input device that is directly connected to the computer 1301. For example, a camera, a microphone, and/or a keyboard that is part of the UI device set 1323 that is part of and/or connected to the computer 1301 in a wired manner captures data and transmits that data to the program 1316 within the persistent storage 1313 of the computer 1301. The data sample in some embodiments includes a text file and/or a table file with circuit characteristic titles that are disposed in cells that are adjacent to respective values for the various characteristics.

In step 112 of the semiconductor migration machine learning process 100, a new semiconductor circuit is built with guidance from the machine learning predictions. Using the predicted performance, circuit specification adjustments are made in a final physical design for processing. Thus, in some embodiments a final result is a manufactured semiconductor circuit. The preceding steps of the process 100 help achieve time and/or resource savings from data capture that would be required without the model prediction. Without the invention and the model prediction, to learn power and frequency performance data for the new circuit the new circuit is built and numerous tests must be run. The present inventions helps provide the information in an earlier stage of design, e.g., in a simulation stage. Using this information, system design can be facilitated because the predictions indicate in advance how the semiconductor circuit will interact with the environment. Thus, business decisions and overall system authorization decisions are facilitated with the machine learning model predictions of the present embodiments.

FIG. 2 illustrates a neural network 200 used in the semiconductor migration machine learning process 100 of FIG. 1 according to at least one embodiment. The neural network 200 includes an input layer 202, hidden layers such as a first hidden layer 204 and a second hidden layer 206, and an output layer 208. The input layer 202 shows multiple input nodes, e.g., three input nodes, for receiving a set of input values. The output layer 208 shows multiple output nodes, e.g., two output nodes, for providing a pair of output values, e.g., two of predicted power, gain, bandwidth, and frequency values for a semiconductor circuit. Although a certain number of nodes and a certain number of hidden layers are shown in the embodiment illustrated in FIG. 2, in other embodiments other numbers of nodes and hidden layers are implemented. In some embodiments as shown in FIG. 2 a node/perceptron of a layer receives input from each of the nodes/perceptrons in the preceding layer. Thus, the meaning of different input values is learned and shared in different layers to help predict the various desired output values.

In an example, one input to the neural network 200 that is input via input layer 202 is a channel width of a semiconductor circuit, e.g., 10 nm, 100 nm, . . . , 500 nm, etc. In the same or another example, an input is a temperature such as a case temperature and/or an operating temperature of a semiconductor circuit, e.g., −40° C., −20° C., . . . 80° C., 100° C. In the same or another example, an input is a drain voltage such as 0.5 V, 0.6 V, . . . 1.2 V, etc. In the same or another example, an input is a technology node such as a designation of 45, 32, 22, 16, etc. In the same or another example, an input is a drain-to-source current and/or a gate capacitance of the semiconductor circuit.

The above-mentioned drain-to-source current and/or gate capacitance are in some embodiments obtained from simulations which are in correspondence with the conditions of physical characteristics of the semiconductor circuit in design. Examples of such physical characteristics include a channel width, temperature, drain voltage, technology node, etc. For example, the drain-to-source current is simulated to be 0.1 A, with the corresponding physical characteristics that the channel width of the semiconductor circuit is 10 nm, the temperature is −40° C., the voltage drain is 0.5 V, and the technology node is 45 nm. For all of these possible combinations (of at least two of the above specified conditions), a respective drain-to-source current is able to be simulated.

The output values, e.g., the predicted power, gain, bandwidth, and/or frequency, which are output from the neural network 200 via the output layer 208 are in some embodiments displayed via a display screen of the computer 901.

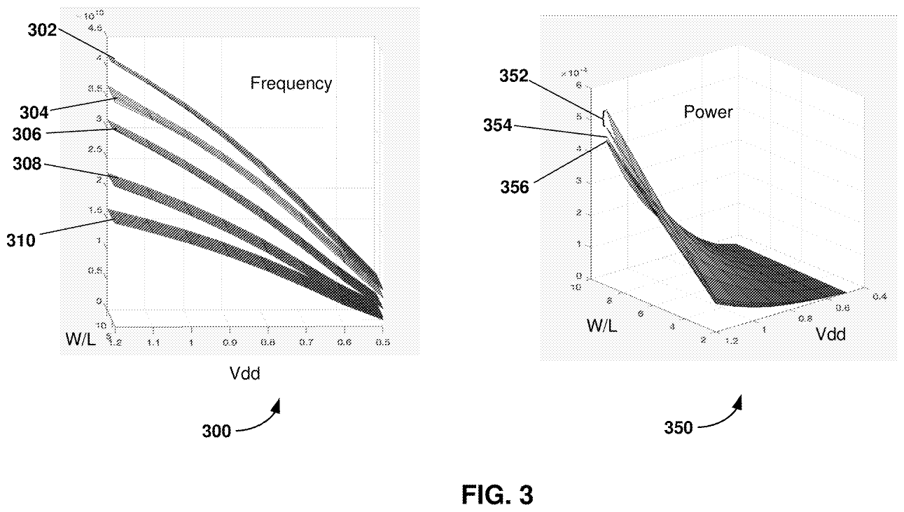

FIG. 3 illustrates output produced by a machine learning model that is trained and used in the process of FIG. 1 according to at least one embodiment. This output is generated in response to a machine learning model trained exclusively on data from known semiconductor circuits. This exclusivity excludes using training data taken from the new semi-conductor circuit in design although it does not exclude all pre-training data, e.g., pre-training data as described in step 102 of the process 100 shown in FIG. 1. In some portions below, this option of training the machine learning model exclusively on data from known semiconductor circuits is referred to as a first option. A first option frequency three-dimensional output 300 is shown in which certain semiconductor circuit physical characteristics are input into the trained machine learning model of the process of FIG. 1 and in response frequency values are produced. Frequency is the vertical axis of the first option frequency three-dimensional output 300. A y-axis of the first option frequency three-dimensional output 300 is a channel width/length ratio of the semiconductor circuit. An x-axis of the first option frequency three-dimensional output 300 is a drain voltage of the semiconductor circuit.

FIG. 3 shows first predicted frequency values 304 for a 16 nm technology node semiconductor circuit design. The machine learning model used to generate the first predicted frequency values 304 was trained using data from a 22 nm technology node semiconductor circuit design, from a 32 nm technology node semiconductor circuit design, and from a 45 nm technology node semiconductor circuit design. Frequency values from these three data sets were used as part of the training data for the machine learning model and are shown as 22 nm technology node frequency values 306, 32 nm technology node frequency values 308, and 45 nm technology node frequency values 310. The first predicted frequency values 304 for a 16 nm technology node semiconductor circuit design are generated without needing to physically produce the 16 nm technology node semiconductor circuit. After subsequent physical manufacturing of this 16 nm technology node semiconductor circuit, true first frequency values 302 for this circuit are obtained through physical testing of the manufactured semiconductor circuit. Comparison of the first predicted frequency values 304 and the true first frequency values 302 shows reasonable success in the prediction so that time/resource savings are achieved with the training and usage of the machine learning model as described herein.

FIG. 3 also shows a first option power three-dimensional output 350 in which certain semiconductor circuit physical characteristics are input into the trained machine learning model of the process of FIG. 1 and, in response, power values are produced. Power is the vertical axis of the first option power three-dimensional output 350. The other two axes are the same as for the first option frequency three-dimensional output 300. FIG. 3 shows first predicted power values 354 for a 16 nm technology node semiconductor circuit design. Known semiconductor power values 352 from the known semiconductors were used as part of the training data for the machine learning model and are taken from 22 nm technology node power values, 32 nm technology node power values, and 45 nm technology node power values. The power values from the 22 nm, 32 nm, and 45 nm technology nodes are close together so are labeled with one reference label (352) in the first option power three-dimensional output 350 in FIG. 3. The first predicted power values 354 for a 16 nm technology node semiconductor=r circuit design are generated without needing to physically produce the 16 nm technology node semiconductor circuit. After subsequent physical manufacturing of this 16 nm technology node semiconductor circuit, true first power values 356 for this circuit are obtained through physical testing of the manufactured semiconductor circuit. Comparison of the first predicted power values 354 and the true first power values 356 shows reasonable success in the prediction so that time/resource savings are achieved with the training and usage of the machine learning model as described herein.

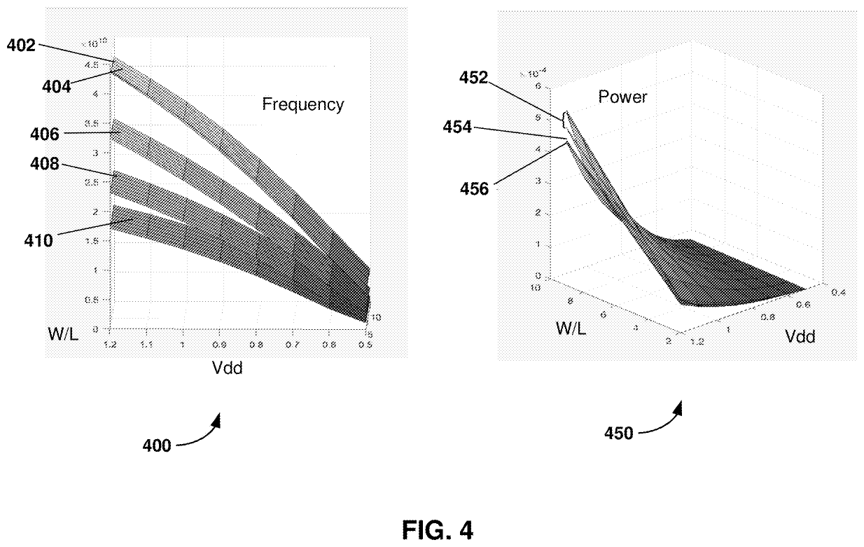

FIG. 4 illustrates output produced by a machine learning model that is trained and used in the process of FIG. 1 according to at least one embodiment. This output is generated in response to a machine learning model trained on data from known semiconductor circuits and on a small amount of data obtained for the new semiconductor circuit that is in design. In some portions below, this option of training the machine learning model on both data from known semiconductor circuits and on a small amount of data obtained for the new semiconductor circuit is referred to as a second option. The second option training occurs in various embodiments with or without the pre-training of step 102 of the process 100 shown in FIG. 1. The three-dimensional models shown in FIG. 4 use the same axes meanings as were used for the three-dimensional models shown in FIG. 3. Thus, FIG. 4 illustrates the effectiveness of the second option as compared to the first option.

FIG. 4 shows a second option frequency three-dimensional output 400 in which certain semiconductor circuit physical characteristics are input into the trained machine learning model of the process of FIG. 1 and, in response, frequency values are produced. FIG. 4 shows second predicted frequency values 404 for a 16 nm technology node semiconductor circuit design. The machine learning model was trained using data from a 22 nm technology node semiconductor circuit design, from a 32 nm technology node semiconductor circuit design, and from a 45 nm technology node semiconductor circuit design. Frequency values from these three data sets were used as part of the training data for the machine learning model and are shown as 22 nm technology node frequency values 406, 32 nm technology node frequency values 408, and 45 nm technology node frequency values 410.

As part of this second option, some physical characteristics of the 16 nm technology node were also used to help train the machine learning model. These physical characteristics were obtained through simulation of a virtual circuit or through measurements from physical tests of a manufactured semiconductor circuit of the new design. These physical characteristics included values such as gate capacitance and/or drain-to-source current.

True second frequency values 402 for this circuit are obtained through physical testing after manufacturing of the 16 nm technology node semiconductor circuit. The true second frequency values 402 are the same values as the true first frequency values 302 shown in FIG. 3. Comparison of the second predicted frequency values 404 and the true second frequency values 402 shows reasonable success in the prediction so that time/resource savings are achieved with the training and usage of the machine learning model as described herein. A comparison of FIGS. 3 and 4 also shows that the option two generated predictions more closely approximated to the true values than were achieved by the option one generated predictions. Thus, using some values, e.g., a small number of values, from the semiconductor circuit in design as part of the training data helps produce more accurate predictions.

FIG. 4 also shows a second option power three-dimensional output 450 in which certain semiconductor circuit physical characteristics are input into the trained machine learning model of the process of FIG. 1 and, in response, power values are produced. The axes meanings are the same for the second option power three-dimensional output 450 as they were for the first option power three-dimensional output 350 shown in FIG. 3. FIG. 4 shows second predicted power values 454 for a 16 nm technology node semiconductor circuit that is in design. Known semiconductor power values 452 from the known semiconductors were used as part of the training data for the machine learning model and are taken from 22 nm technology node power values, 32 nm technology node power values, and 45 nm technology node power values. The power values from the 22 nm, 32 nm, and 45 nm technology nodes are close together so are labeled with one reference label (452) in the second option power three-dimensional output 450 in FIG. 4. The second predicted power values 454 for a 16 nm technology node semiconductor circuit design are generated without needing to physically produce the 16 nm technology node semiconductor circuit. True second power values 456 for this circuit are obtained through physical testing. The true second option power values 452 are the same values as the true first option power values 352 shown in FIG. 3. A comparison of the second predicted power values 454 and the true second power values 456 shows reasonable success in the prediction so that time/resource savings are achieved with the training and usage of the machine learning model as described herein.

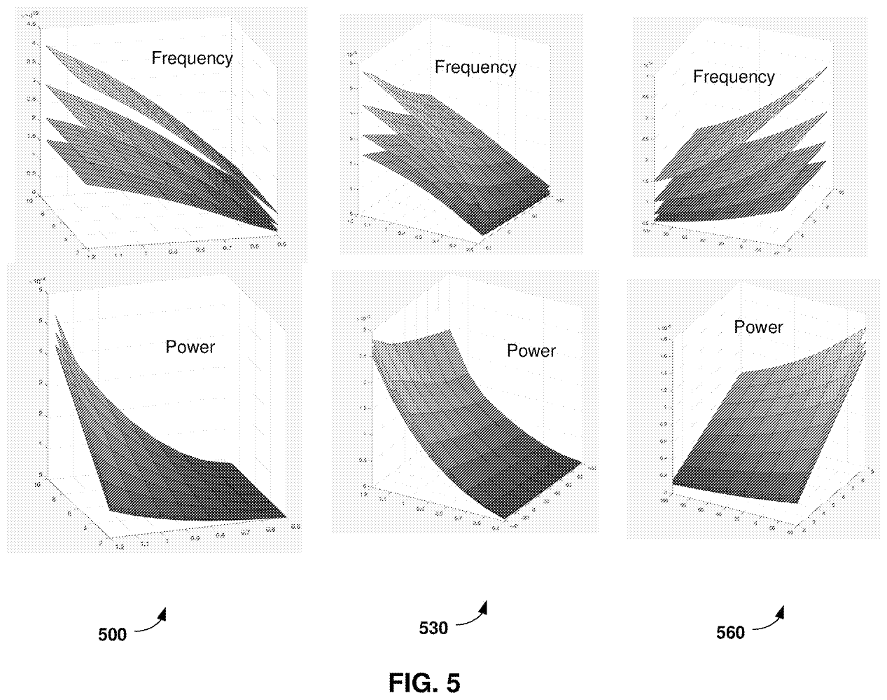

FIG. 5 illustrates sets of output produced by a machine learning model that is trained and used in the process of FIG. 1 according embodiments. These sets of output are varied based on different sets of semiconductor physical characteristics that are input regarding the new semiconductor circuit that is in design. FIG. 5 illustrates a temperature-invariant set 500, a channel width/channel length ratio-invariant set 530, and a drain voltage invariant set 560. Each of the three sets 500, 530, and 560 shows power predictions and frequency predictions based on the input physical characteristics. Of the four layers of frequency values shown in the various three-dimensional drawings in FIG. 5, the lower three represent true values taken from known technology nodes of 22 nm, 32 nm, and 45 nm (respectively going from higher to lower in the illustration). The predicted frequency values are shown as the upper-most layer of values. Of the layers of power values shown in the various three-dimensional drawings in FIG. 5, the lowest layer is predicted power values. The other layers represent true values taken from known technology nodes.

For the temperature-invariant set 500, the operating temperature of the semiconductor circuit in design is set for 20° C. The y-axis represents channel width/channel length ratio. The x-axis represents drain voltage.

For the channel width/channel length ratio-invariant set 530, the channel width/channel length ratio is set as a value of four. The y-axis represents temperature. The x-axis represents drain voltage.

For the drain voltage invariant set 560, the drain voltage is set as 0.8 V. The y-axis represents channel width/channel length ratio. The x-axis represents temperature.

Thus, FIG. 5 illustrates that with the embodiments described herein sets of physical characteristics and performance characteristics from old/known semiconductor circuits are useable to train a machine learning model which then is capable of predicting performance characteristics for a new semiconductor design in response to receiving some physical characteristics of the new semiconductor design as input.

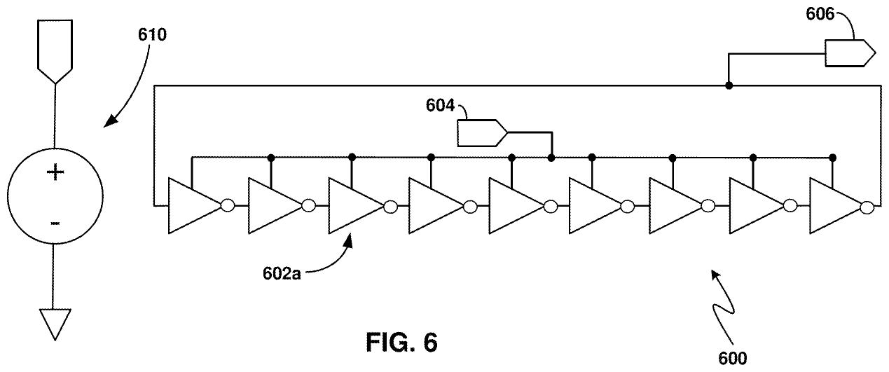

FIG. 6 illustrates a design for a multi-stage semiconductor circuit for which the process of FIG. 1 is implemented according to at least one embodiment. In some embodiments, the data from step 104 that is obtained from a known semiconductor circuit is obtained via simulation. FIG. 6 shows a nine-stage ring oscillator 600 in which known semiconductor circuits were implemented for the various inverters such as in the first inverter stage 602a. The nine-stage ring oscillator 600 includes a voltage drain 604, an output voltage 606, and a voltage supplier 610.

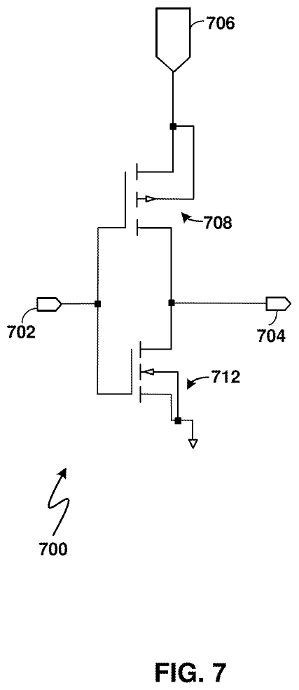

FIG. 7 illustrates details of one of the stages of the multi-stage semiconductor circuit shown in FIG. 6, e.g., of the first inverter stage 602a. FIG. 7 shows inverter 700 that includes an input voltage 702, an output voltage 704, and a voltage drain 706. The inverter 700 includes a first semiconductor circuit 708, e.g., an M1 PMOS16, and a second semiconductor circuit 712, e.g., an M2 NMOS 16. The first semiconductor circuit 708 and the second semiconductor circuit 712 in some embodiments are known technology nodes such as 22 nm technology nodes, 32 nm technology nodes, and/or 45 nm technology nodes.

The process 100 shown in FIG. 1 in one embodiment uses data from this setup shown in FIGS. 6 and 7 in step 104 to obtain data to train the machine learning model. In some embodiments, the same multi-stage design could be used as the new semiconductor design for step 110 but with one or more semiconductor circuits from new technology nodes implemented as the first semiconductor circuit 708 and/or the second semiconductor circuit 712. The machine learning model trained in the process 100 is also able to provide predictions for new semiconductor circuits with stages and inverter designs which differ from those that were used for obtaining the training data in step 104.

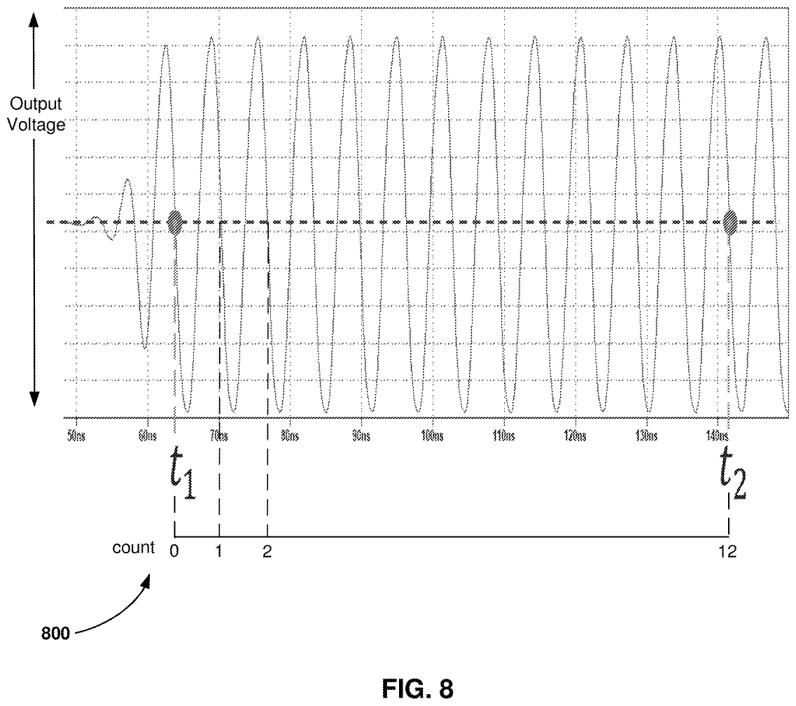

FIG. 8 illustrates voltage frequency parameter details used for simulating operation of the multi-stage design shown in FIGS. 6 and 7 to simulate performance characteristics with the known semiconductor circuits. In this instance, simulation software is useable to perform tests to determine the values that are obtained in step 104 of the process 100. The values are part of the training data that are used to train the machine learning model in step 108. FIG. 8 shows a voltage output vs. time graph 800 which tracks voltage output from the nine-stage ring oscillator 600, in the depicted instance with semiconductor circuits from technology node 32 implemented as the first semiconductor circuit 708 and the second semiconductor circuit 712. The voltage output vs. time graph 800 tracks counts of how many times the voltage output value crosses the zero value indicated by a horizontal dashed line. For the depicted instance, from the time t₁ to the time t₂ the voltage had a count of twelve times crossing the zero value. For the simulation, formulas of:

$$Frequency = \frac{1}{{t}_{2} - {t}_{1}} [ Count ]$$

$$Power = \frac{1}{{t}_{2} - {t}_{1}} {\int }_{{t}_{1}}^{{t}_{2}} VDD \times {I}_{VDD} ( t ) dt$$

are used where VDD is the drain voltage in the circuit and I_{VDD} is the current associated with the drain voltage in the circuit.

In some embodiments, various simulations are performed with varying the channel width/channel length ratio over various amounts, e.g., over eight amounts increasing in increments of one—starting from a value of two and concluding with a value of nine. In some embodiments, various simulations are performed with varying the temperature over various amounts, e.g., over eight amounts in increments of increasing twenty degrees Celsius starting from negative forty degrees Celsius and proceeding up to 100 degrees Celsius. In some embodiments, various simulations are performed with varying the drain voltage over various amounts, e.g., over eight amounts in increments of increasing 0.1 V starting from 0.5 V and proceeding up to 1.2 V. In some embodiments, various simulations are performed with varying the technology node over four types—16 nm, 22 nm, 32 nm, and 45 nm. Using these various iterations, some embodiments include obtaining 2048 simulation results based on 8×8×8×4=2048. These simulation results produce some data for training the machine learning model in step 108 of the process 100.

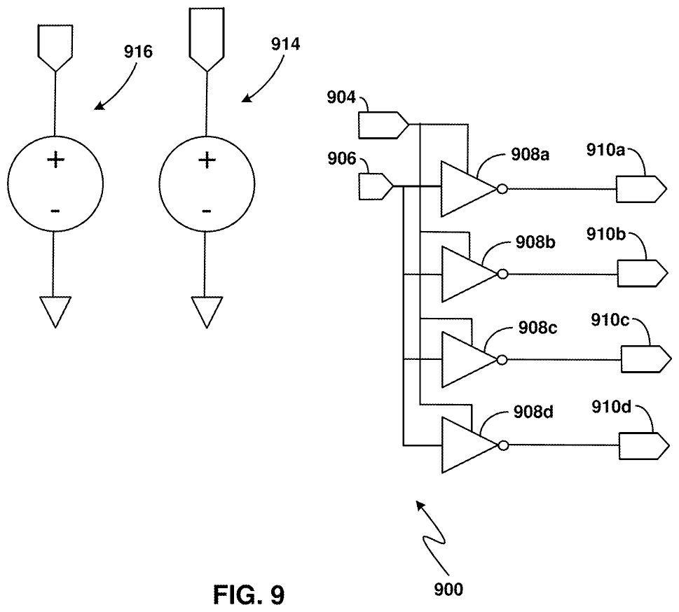

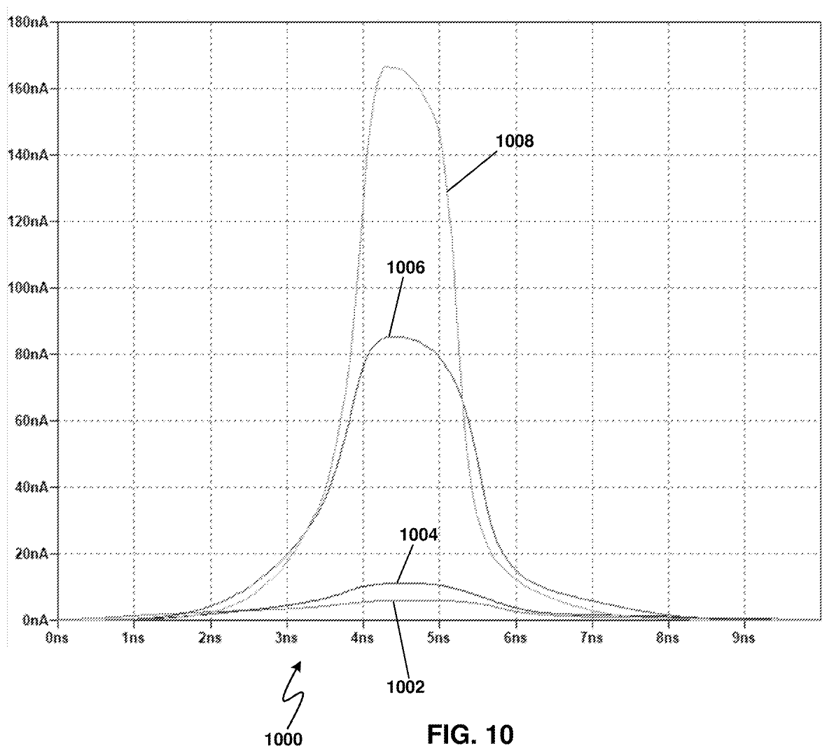

FIG. 9 illustrates a setup, e.g., a simulation setup, for collecting gate capacitance data for use in the process of FIG. 1. Using techniques shown in FIGS. 9 and 10, data is gathered that is used in the pre-training step 102 of the process 100 shown in FIG. 1 in some embodiments. FIG. 9 shows a capacitance determination setup 900 in which capacitances of various single inverters are determined. Specifically, in the depicted embodiment the capacitances for first inverter 908a, second inverter 908b, third inverter 908c, and fourth inverter 908d are determined using a drain voltage 904, a gate voltage 906, and output voltages for each of the inverters, respectively-specifically, a first output voltage 910a, a second output voltage 910b, a third output voltage 910c, and a fourth output voltage 910d. Drain voltage supplier 914 provides voltage to the drain voltage 904. Gate voltage supplier 916 provides voltage to the gate voltage 906.

Using the current graph 1000 shown in FIG. 10, the program 1316 takes recorded values from the various inverters (either through physical tests or through simulation) and determines capacitances for use for the model pre-training data. The current graph 1000 graphs current (y-axis) vs. time (x-axis) for values for the various inverters. The various simulation types and numbers are similar and scalable as those 2048 simulations described above with respect to FIG. 8. FIG. 10 shows the first current curve 1002 which is the current from the measurement from the first inverter 908a shown in FIG. 9 which in the depicted embodiment is for a semiconductor circuit in 16 nm technology node-type. FIG. 10 shows the second current curve 1004 which is the current from the measurement from the second inverter 908b shown in FIG. 9 which in the depicted embodiment is for a semiconductor circuit in 22 nm technology node-type. FIG. 10 shows the third current curve 1006 which is the current from the measurement from the third inverter 908c shown in FIG. 9 which in the depicted embodiment is for a semiconductor circuit in 32 nm technology node-type. FIG. 10 shows the fourth current curve 1008 which is the current from the measurement from the fourth inverter 908d shown in FIG. 9 which in the depicted embodiment is for a semiconductor circuit in 45 nm technology node-type. These current curves show that the newer technology nodes are capable of operating at lower levels of current and with lower peaks of current.

For the determination, e.g., the simulation, formulas of:

$$I = C \frac{{dV}_{g}}{dt}$$

$${V}_{g} ( {t}_{1} ) = 0 , {V}_{g} ( {t}_{2} ) = {V}_{dd}$$

$$C = {V}_{dd} {\int }_{{t}_{1}}^{{t}_{2}} I ( t ) dt$$

are used where C is the capacitance. These formulas help determine capacitance values to use for pre-training data.

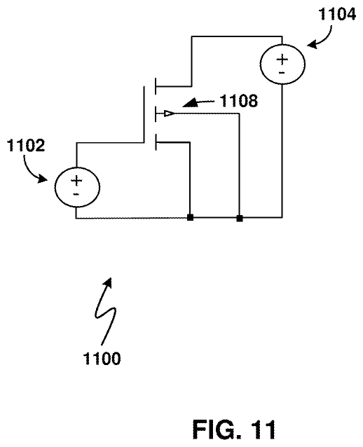

FIG. 11 illustrates a circuit device design for obtaining drain-to-source current data for use in the process of FIG. 1 for pre-training the machine learning model according to at least one embodiment. FIG. 11 illustrates a single circuit design setup 1100 which is useable to obtain drain-to-source current data for circuits. This drain-to-source current data is useable in step 102 of the process 100 to pre-train the machine learning model. The single circuit design setup 1100 is useable with physical tests on manufactured circuits or in a simulation setup for virtual circuits, for collecting the drain-to-source current data. Specifically, in the depicted embodiment the device is an n-channel transistor (NFET) with a single semiconductor circuit 1108 that works in conjunction with a drain-to-source applied voltage 1104 and a gate-to-source applied voltage 1102.

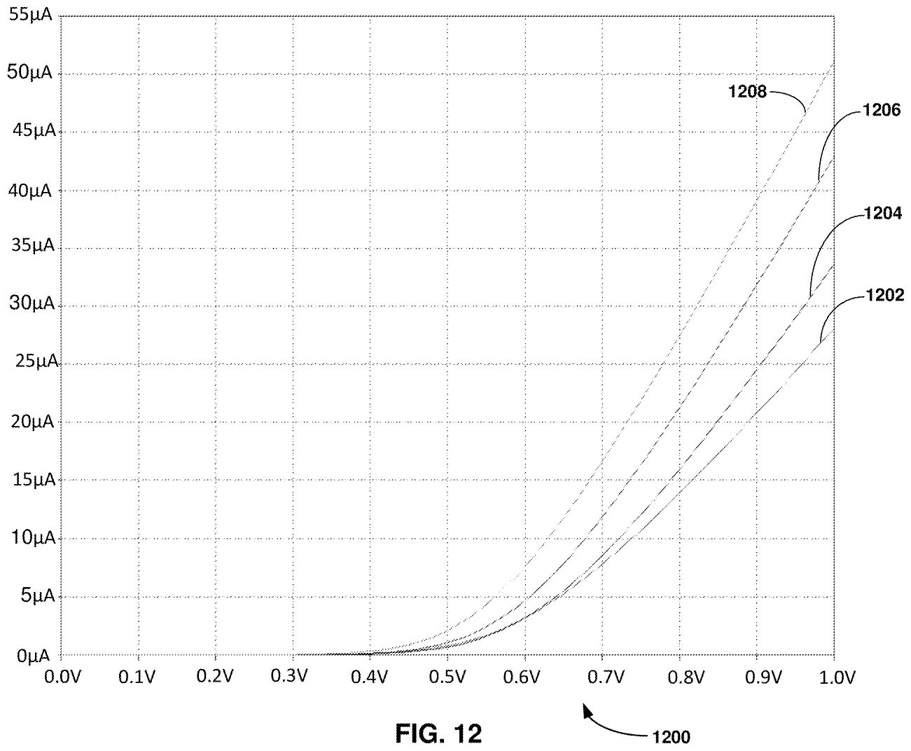

Using the drain-to-source current graph 1200 shown in FIG. 12, the program 1316 takes recorded values from the single circuit design setup 1100 (either through physical tests or through simulation) and determines drain-to-source values that are usable as pre-training data. The drain-to-source current graph 1200 includes current as the y-axis and voltage as the x-axis. Thus, the four curves shown are I-V curves for various semiconductor circuits implemented in the single circuit design setup 1100. The various simulation types, values, and type numbers are similar and scalable as those 2048 simulations described above with respect to FIGS. 8 and 10.

FIG. 12 shows the first I-V curve 1202 which is the I-V curve from the measurement from a 16 nm technology node type semiconductor circuit being implemented in the single circuit design setup 1100 as the single semiconductor circuit 1108. FIG. 12 shows the second I-V curve 1204 which is the I-V curve from the measurement from a 22 nm technology node type semiconductor circuit being implemented in the single circuit design setup 1100 as the single semiconductor circuit 1108. FIG. 12 shows the third I-V curve 1206 which is the I-V curve from the measurement from a 32 nm technology node type semiconductor circuit being implemented in the single circuit design setup 1100 as the single semiconductor circuit 1108. FIG. 12 shows the fourth I-V curve 1208 which is the I-V curve from the measurement from a 45 nm technology node type semiconductor circuit being implemented in the single circuit design setup 1100 as the single semiconductor circuit 1108.

It may be appreciated that FIGS. 1-12 provide only illustrations of certain embodiments and do not imply any limitations with regard to how different embodiments may be implemented. Many modifications to the depicted embodiment(s), e.g., to particular steps, elements, inputs, outputs, and/or order of depicted methods or components of a neural network, may be made based on design and implementation requirements.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1300 shown in FIG. 13 contains an example of an environment for the execution of at least some of the computer code involved in performing the inventive methods, such as machine learning for semiconductor circuit feature migration program 1316. In addition to machine learning for semiconductor circuit feature migration program 1316, computing environment 1300 includes, for example, computer 1301, wide area network (WAN) 1302, end user device (EUD) 1303, remote server 1304, public cloud 1305, and private cloud 1306. In this embodiment, computer 1301 includes processor set 1310 (including processing circuitry 1320 and cache 1321), communication fabric 1311, volatile memory 1312, persistent storage 1313 (including operating system 1322 and machine learning for semiconductor circuit feature migration program 1316, as identified above), peripheral device set 1314 (including user interface (UI) device set 1323, storage 1324, and Internet of Things (IoT) sensor set 1325), and network module 1315. Remote server 1304 includes remote database 1330. Public cloud 1305 includes gateway 1340, cloud orchestration module 1341, host physical machine set 1342, virtual machine set 1343, and container set 1344.

COMPUTER 1301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1330. As is well understood in the art of computer technology, and depending upon the technology, performance of a computer-implemented method may be distributed among multiple computers and/or between multiple locations. On the other hand, in this presentation of computing environment 1300, detailed discussion is focused on a single computer, specifically computer 1301, to keep the presentation as simple as possible. Computer 1301 may be located in a cloud, even though it is not shown in a cloud in FIG. 13. On the other hand, computer 1301 is not required to be in a cloud except to any extent as may be affirmatively indicated.

PROCESSOR SET 1310 includes one, or more, computer processors of any type now known or to be developed in the future. Processing circuitry 1320 may be distributed over multiple packages, for example, multiple, coordinated integrated circuit chips. Processing circuitry 1320 may implement multiple processor threads and/or multiple processor cores. Cache 1321 is memory that is located in the processor chip package(s) and is typically used for data or code that should be available for rapid access by the threads or cores running on processor set 1310. Cache memories are typically organized into multiple levels depending upon relative proximity to the processing circuitry. Alternatively, some, or all, of the cache for the processor set may be located “off chip.” In some computing environments, processor set 1310 may be designed for working with qubits and performing quantum computing.

Computer readable program instructions are typically loaded onto computer 1301 to cause a series of operational steps to be performed by processor set 1310 of computer 1301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1321 and the other storage media discussed below. The program instructions, and associated data, are accessed by processor set 1310 to control and direct performance of the inventive methods. In computing environment 1300, at least some of the instructions for performing the inventive methods may be stored in machine learning for semiconductor circuit feature migration program 1316 in persistent storage 1313.

COMMUNICATION FABRIC 1311 is the signal conduction path that allows the various components of computer 1301 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1312 is any type of volatile memory now known or to be developed in the future. Examples include dynamic type random access memory (RAM) or static type RAM. Typically, volatile memory 1312 is characterized by random access, but this is not required unless affirmatively indicated. In computer 1301, the volatile memory 1312 is located in a single package and is internal to computer 1301, but, alternatively or additionally, the volatile memory may be distributed over multiple packages and/or located externally with respect to computer 1301.

PERSISTENT STORAGE 1313 is any form of non-volatile storage for computers that is now known or to be developed in the future. The non-volatility of this storage means that the stored data is maintained regardless of whether power is being supplied to computer 901 and/or directly to persistent storage 1313. Persistent storage 1313 may be a read only memory (ROM), but typically at least a portion of the persistent storage allows writing of data, deletion of data and re-writing of data. Some familiar forms of persistent storage include magnetic disks and solid state storage devices. Operating system 1322 may take several forms, such as various known proprietary operating systems or open source Portable Operating System Interface-type operating systems that employ a kernel. The code included in machine learning for semiconductor circuit feature migration program 1316 typically includes at least some of the computer code involved in performing the inventive methods.

PERIPHERAL DEVICE SET 1314 includes the set of peripheral devices of computer 1301. Data communication connections between the peripheral devices and the other components of computer 1301 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 1323 may include components such as a display screen, speaker, microphone, wearable devices (such as goggles and smart watches), keyboard, mouse, printer, touchpad, game controllers, and haptic devices. Storage 1324 is external storage, such as an external hard drive, or insertable storage, such as an SD card. Storage 1324 may be persistent and/or volatile. In some embodiments, storage 1324 may take the form of a quantum computing storage device for storing data in the form of qubits. In embodiments where computer 1301 is required to have a large amount of storage (for example, where computer 1301 locally stores and manages a large database) then this storage may be provided by peripheral storage devices designed for storing exceptionally large amounts of data, such as a storage area network (SAN) that is shared by multiple, geographically distributed computers. IoT sensor set 1325 is made up of sensors that can be used in Internet of Things applications. For example, one sensor may be a thermometer and another sensor may be a motion detector.

NETWORK MODULE 1315 is the collection of computer software, hardware, and firmware that allows computer 1301 to communicate with other computers through WAN 1302. Network module 1315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1315 are performed on the same physical hardware device. In other embodiments (for example, embodiments that utilize software-defined networking (SDN)), the control functions and the forwarding functions of network module 1315 are performed on physically separate devices, such that the control functions manage several different network hardware devices. Computer readable program instructions for performing the inventive methods can typically be downloaded to computer 1301 from an external computer or external storage device through a network adapter card or network interface included in network module 1315.

WAN 1302 is any wide area network (for example, the internet) capable of communicating computer data over non-local distances by any technology for communicating computer data, now known or to be developed in the future. In some embodiments, the WAN 1302 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1303 is any computer system that is used and controlled by an end user (for example, a customer of an enterprise that operates computer 1301) and may take any of the forms discussed above in connection with computer 1301. EUD 1303 typically receives helpful and useful data from the operations of computer 1301. For example, in a hypothetical case where computer 1301 is designed to provide a recommendation to an end user, this recommendation would typically be communicated from network module 915 of computer 1301 through WAN 1302 to EUD 1303. In this way, EUD 1303 can display, or otherwise present, the recommendation to an end user. In some embodiments, EUD 1303 may be a client device, such as thin client, heavy client, mainframe computer, desktop computer and so on.

REMOTE SERVER 1304 is any computer system that serves at least some data and/or functionality to computer 1301. Remote server 1304 may be controlled and used by the same entity that operates computer 1301. Remote server 1304 represents the machine(s) that collect and store helpful and useful data for use by other computers, such as computer 1301. For example, in a hypothetical case where computer 1301 is designed and programmed to provide a recommendation based on historical data, then this historical data may be provided to computer 1301 from remote database 1330 of remote server 1304.

PUBLIC CLOUD 1305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1305 is performed by the computer hardware and/or software of cloud orchestration module 1341. The computing resources provided by public cloud 1305 are typically implemented by virtual computing environments that run on various computers making up the computers of host physical machine set 1342, which is the universe of physical computers in and/or available to public cloud 1305. The virtual computing environments (VCEs) typically take the form of virtual machines from virtual machine set 1343 and/or containers from container set 1344. It is understood that these VCEs may be stored as images and may be transferred among and between the various physical machine hosts, either as images or after instantiation of the VCE. Cloud orchestration module 1341 manages the transfer and storage of images, deploys new instantiations of VCEs and manages active instantiations of VCE deployments. Gateway 1340 is the collection of computer software, hardware, and firmware that allows public cloud 1305 to communicate through WAN 1302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1306 is similar to public cloud 1305, except that the computing resources are only available for use by a single enterprise. While private cloud 1306 is depicted as being in communication with WAN 1302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1305 and private cloud 1306 are both part of a larger hybrid cloud.

The computer 1301 in some embodiments also hosts one or more machine learning models such as the semiconductor performance prediction machine learning model. A machine learning model in one embodiment is stored in the persistent storage 1313 of the computer 1301. A received data sample is input to the machine learning model via an intra-computer transmission within the computer 1301, e.g., via the communication fabric 1311, to a different memory region hosting the machine learning model.

In some embodiments, one or more machine learning models are stored in computer memory of a computer positioned remotely from the computer 1301, e.g., in a remote server 1304 or in an end user device 1303. In this embodiment, the program 1316 works remotely with this machine learning model to train and/or use same. Training instructions are sent via a transmission that starts from the computer 1301, passes through the WAN 1302, and ends at the destination computer that hosts the machine learning model. Thus, in some embodiments the program 1316 at the computer 1301 or another instance of the software at a central remote server performs routing of training instructions to multiple server/geographical locations in a distributed system.

In such embodiments, a remote machine learning model is configured to send its output back to the computer 1301 so that inference and semiconductor performance predictions generated from providing input to the trained model are provided and presented to a user. The machine learning model receives a copy of the new input data, performs machine learning analysis on the received sample, and transmits the results, e.g., circuit performance characteristics such as circuit power and/or frequency, back to the computer 1301.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises,” “comprising,” “includes,” “including,” “has,” “have,” “having,” “with,” and the like, when used in this specification, specify the presence of stated features, integers, steps, operations, elements, and/or components, but does not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

The flowchart and block diagrams in the Figures illustrate the architecture, functionality, and operation of possible implementations of systems, methods, and computer program products according to various embodiments. In this regard, each block in the flowchart, pipeline, and/or block diagrams may represent a module, segment, or portion of instructions, which comprises one or more executable instructions for implementing the specified logical function(s).

What is claimed is:

1. A computer-implemented method comprising using a trained machine learning model to predict performance of a semiconductor circuit, wherein the using comprises inputting, to the trained machine learning model, semiconductor physical characteristics of the semiconductor circuit and in response receiving, as output from the trained machine learning model, predicted performance characteristics for the semiconductor circuit, wherein the trained machine learning model was trained on training data obtained from a prior known semiconductor circuit.

2. The method of claim 1, wherein the semiconductor physical characteristics are selected from a group consisting of channel width, channel length, temperature, supply voltage, and technology node.

3. The method of claim 1, wherein the semiconductor performance characteristics are selected from a group consisting of frequency, gain, bandwidth, and power.

4. The method of claim 1, wherein the machine learning model also includes, as inputs, device level information for a device to which the semiconductor circuit belongs.

5. The method of claim 4, wherein the device level information comprises at least one member selected from a group consisting of capacitance and drain-to-source current.

6. The method of claim 1, wherein the machine learning model is a neural network.

7. The method of claim 1, wherein the machine learning model is a multi-layer perceptron network.

8. The method of claim 1, wherein the semiconductor circuit is selected from a group consisting of an analog circuit, a ring oscillator, a bandgap reference, and an op-amplifier.

9. A computer-implemented method comprising:
training a machine learning model with training data obtained from a known semiconductor circuit, wherein the training data comprises:
inputs to the machine learning model that are semiconductor physical characteristics and
outputs from the machine learning model that are semiconductor performance characteristics;
wherein the outputs constitute labels so that the training is supervised training, and wherein the training comprises optimizing weights of the machine learning model so that the machine learning model predicts the outputs based on the inputs.

10. The method of claim 9, wherein the semiconductor physical characteristics are selected from a group consisting of channel width, channel length, temperature, supply voltage, and technology node.

11. The method of claim 9, wherein the semiconductor performance characteristics are selected from a group consisting of frequency, gain, bandwidth, and power.

12. The method of claim 9, wherein the inputs further comprise device level information for a device to which the semiconductor circuit belongs.

13. The method of claim 12, wherein the device level information comprises at least one member selected from a group consisting of capacitance and drain-to-source current.

14. The method of claim 9, wherein the machine learning model is a neural network.

15. The method of claim 9, wherein the machine learning model is a multi-layer perceptron network.

16. The method of claim 9, wherein the semiconductor circuit is selected from a group consisting of an analog circuit, a ring oscillator, a bandgap reference, and an op-amplifier.

17. The method of claim 9, wherein the training data further comprises data from another semiconductor circuit.

18. The method of claim 9, further comprising pre-training the machine learning model by teaching the machine learning model to predict drain-to-source current and gate capacitance of at least one of the semiconductor circuit and another semiconductor circuit.

19. A computer program product comprising:
a set of one or more computer-readable storage media; and
program instructions, collectively stored in the set of one or more storage media, for causing a processor set to perform the following computer operations:
using a trained machine learning model to predict performance of a semiconductor circuit, wherein the using comprises inputting, to the trained machine learning model, semiconductor physical characteristics of the semiconductor circuit and in response receiving, as output from the trained machine learning model, predicted performance characteristics for the semiconductor circuit, wherein the trained machine learning model was trained on training data obtained from a prior known semiconductor circuit.

20. A computer system comprising:
a processor set; and
the computer program product of claim 19.
